(19) United States
(12) Patent Application Publication
(10) Pub. No.: US 2024/0347440 A1
(43) Pub. Date: Oct. 17, 2024

(54) OMNIDIRECTIONAL FLEXIBLE LIGHT EMITTING DEVICE

(71) Applicant: FEIT ELECTRIC COMPANY, INC., Pico Rivera, CA (US)

(72) Inventor: John D. Mitchell, JR., Andover, MA (US)

(21) Appl. No.: 18/529,938

(22) Filed: Dec. 5, 2023

Related U.S. Application Data
(63) Continuation of application No. 16/983,747, filed on Aug. 3, 2020, now Pat. No. 11,876,042.

(51) Int. Cl. H01L 23/498; H01L 25/13

(52) U.S. Cl. CPC H01L 23/4985; H01L 23/49838; H01L 25/13

(57) ABSTRACT

An omnidirectional light emitting device is provided. An example device includes a flexible substrate having a substrate length, a first substrate surface, and a second substrate surface. The flexible substrate is configured to be flexibly wrenched about a longitudinal axis that is parallel to the substrate length. The example device further includes a plurality of LED packages disposed on the first substrate surface. Each LED package of the plurality of LED packages is configured to emit light outward from the flexible substrate.

### CROSS-REFERENCE TO RELATED APPLICATIONS

The present application is a continuation of and claims priority to and the benefit of U.S. Nonprovisional patent application Ser. No. 16/983,747, filed Aug. 3, 2020, the contents of which as are hereby incorporated by reference herein in their entirety.

### BACKGROUND

Light emitting devices may comprise light emitting diodes. Light emitting diodes (also referred to herein as LEDs) are semiconductor devices that emit light when an electric current is passed through them. The light is produced when particles that carry the electric current (e.g., electrons and holes) combine together with the semiconductor material of the semiconductor devices. LEDs are described as solid-state devices, which distinguishes them from other lighting technologies that use heated filaments or gas discharge as lighting sources (e.g., incandescent, tungsten halogen lamps; fluorescent lamps).

LEDs are widely used in lighting applications for residential and commercial structures. Light bulbs utilizing LEDs are far more efficient when compared to traditional lighting such as incandescent and fluorescent lights. Most of the energy in LEDs is converted into light and a minimal amount results in heat.

Conventional filament-type lighting devices utilizing LEDs typically have LEDs mounted on one side of the filament. This single-sided configuration of conventional LED filaments provides poor light distribution. To overcome this problem of poor light distribution, conventional solutions have either increased the number of LED filaments mounted in lighting fixtures, and/or employed transparent or translucent filament substrates.

Through applied effort, ingenuity, and innovation many deficiencies of such systems have been solved by developing solutions that are in accordance with the embodiments of the present invention, many examples of which are described in detail herein.

### SUMMARY

Various embodiments are directed to a light emitting device configured for providing omnidirectional light output. In certain embodiments, the light emitting device comprises a flexible substrate having a substrate length, a first substrate surface and a second substrate surface. In embodiments, the flexible substrate is configured to be twisted and/or rotated around a longitudinal axis. In embodiments, the light emitting device further comprises a plurality of LED packages disposed on the first substrate surface. The plurality of LED packages of certain embodiments are configured to emit light outward from the flexible substrate.

In embodiments, the flexible substrate may be configured to be permanently flexible. In certain embodiments, the flexible substrate is configured to be twisted and/or rotated within a range of 0° to 90°, 90° to 180°, or 180° to 360°. The flexible substrate of certain embodiments is configured to radiate heat.

In embodiments, the flexible substrate of the light emitting device may further comprise a circuit board. In embodiments, the circuit board comprises a first and second side. In embodiments, the flexible substrate of the light emitting device further comprises a plurality of LED packages disposed on and/or electrically and mechanically couplable to the first side. In embodiments, the flexible substrate of the light emitting device further comprises a plurality of leads/traces disposed on and/or electrically and mechanically couplable to the first or second side of the circuit board and electrically couplable with the plurality of LED packages. In embodiments, the flexible substrate further comprises driver circuitry disposed on and/or electrically and mechanically couplable to the first side or second side of the circuit board. The driver circuitry of certain embodiments is electrically couplable with the plurality of leads/traces of the circuit board.

In certain embodiments, the plurality of LED packages comprise phosphor-based LED packages. Moreover, the flexible substrate of certain embodiments is of a matching color as a phosphor color of the phosphor-based LED packages. In certain embodiments, the plurality of LED packages are configured to emit blue light.

In certain embodiments, the substrate width and at least one LED package width are the same width. In certain embodiments, the flexible substrate comprises polyamide. The substrate width of certain embodiments is 1 to 2 mm, and the substrate length is 5 cm.

Various embodiments directed to a lighting apparatus configured for providing omnidirectional light output are provided. In embodiments, a lighting apparatus may comprise a transparent housing. The transparent housing of certain embodiments may be configurable to house a light emitting device. The transparent housing of certain embodiments may be configurable to protect the integrity of the light emitting device housed within. For example, in various embodiments, the transparent housing may be infused with a gas that is conducive for inhibiting the introduction of moisture and/or other contaminants into the transparent housing. For example, the transparent housing may be infused with dry air or an inert gas to this end.

In embodiments, a lighting apparatus may comprise a base for electrically coupling with a lighting socket. In embodiments, a lighting apparatus may comprise a light emitting device. The light emitting device of certain embodiments is electrically couplable with the base and housed within the transparent housing. The light emitting device of certain embodiments comprises a flexible substrate having a substrate length, a substrate width, a first substrate surface and a second substrate surface. In embodiments, the flexible substrate is configured to be twisted and/or rotated around a longitudinal axis that is parallel to the substrate length. In embodiments, a plurality of LED packages are disposed on the first substrate surface. The LED packages of certain embodiments each comprise an LED package width and are configured to emit light outward from the flexible substrate.

In embodiments, the plurality of LED packages comprise phosphor-based LED packages.

In embodiments, the flexible substrate is of a matching color as a phosphor color of the phosphor-based LED packages.

The substrate width and each LED package width of certain embodiments are the same width.

In embodiments, the base comprises an Edison-type base.

In embodiments, the base comprises a G4-type base.

In embodiments, the base comprises a G6.35-type base.

In embodiments, the base comprises a G6.35-type base.

In embodiments, the base comprises a G9-type base.

The base of certain embodiments is mechanically and/or electrically couplable to the circuit board of the light emitting device of certain embodiments, such that electrical current is provided to the light emitting device.

This Summary does not attempt to completely signify any particular innovation, embodiment, or example as it can be used in commerce. Additionally, this Summary is not intended to signify essential elements of an innovation, embodiment or example or to limit the scope of the subject matter of this disclosure.

The innovations, embodiments, and/or examples found within this disclosure are not all-inclusive, but rather describe the basic significance of the subject matter. Accordingly, one use of this Summary is as a prelude to a Detailed Description presented later.

### BRIEF DESCRIPTION OF THE DRAWINGS

The following Detailed Description, Figures, and appended Claims signify the nature and advantages of the innovations, embodiments and/or examples of the claimed inventions. All of the Figures signify innovations, embodiments, and/or examples of the claimed inventions for purposes of illustration only and do not limit the scope of the claimed inventions. Such Figures are not necessarily drawn to scale and are part of the Disclosure.

In the Figures, similar components or features may have the same, or similar, reference signs in the form of labels (such as alphanumeric symbols, e.g., reference numerals), and may signify similar or equivalent functionality. Further, various components of the same type may be distinguished by following the reference label by a dash and a second label that distinguishes among the similar components. If only the first reference label is used in the specification, the description is applicable to any one of the similar components having the same first reference label irrespective of the second reference label. A brief description of the Figures is below.

FIGS. 1A, 1B, and IC are top views of an exemplary flexible substrate configured in accordance with embodiments of the present disclosure;

FIG. 2A is a top view illustration of the range of rotation of an exemplary flexible substrate configured in accordance with embodiments of the present disclosure;

FIG. 2B-2C are perspective views of the range of rotation of an exemplary flexible substrate configured in accordance with embodiments of the present disclosure;

FIG. 3 is a perspective view of an exemplary flexible substrate configured in accordance with embodiments of the present disclosure;

FIG. 4 illustrates an exemplary lighting apparatus in accordance with embodiments of the present disclosure; and

FIGS. 5A-5B are perspective views illustrating a flexible substrate according to various embodiments of the present disclosure.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Lighting emitting devices according to the present disclosure provide greater functionality over conventional lighting devices. Conventional lighting devices employing flexible substrates are typically configured with a first flexible substrate mounted to a second substrate. The second substrate is typically complex in shape. Such a heterogeneous arrangement of substrates contributes to deformation, fracture, delamination, etc., because of the different compositions of the first and second substrates.

Light emitting devices according to the present disclosure may employ a single, twistable substrate. Light emitting devices according to the present disclosure therefore obviate the need for a second substrate, lowering manufacturing costs and providing greater functionality.

Furthermore, a twistable substrate according to the present disclosure may be configured into various shapes as needed. Such adaptability provides greater functionality and light dispersion over conventional designs. For example, a twistable substrate according to the present disclosure may be configured to substantially define a helical shape. The twistable substrate of various embodiments may then, for example, be configured to comprise a plurality of LEDs and suspend between supporting wires, thereby overcoming the deficiencies of conventional LED filament devices.

Conventional devices are typically manufactured so that a flexible substrate accentuates the shape of a standard (e.g., Edison-style) light bulb. Such a conventional design is deficient because it results in a nonoptimal disposition of the LEDs within the light bulb. On the other hand, flexible substrates according to the present disclosure are inherently more geometrically efficient.

The substantially helical configuration of the above example may dispose the LEDs within the light bulb more efficiently. This is because the geometry of a helix ensures that some portion of the light emitted from each LED will maintain a constant angle with the flexible substrate itself. More light from the plurality of LEDs may therefore be emitted outward from the lighting emitting device; less light may be wasted. A flexible substrate according to the present disclosure may be configured in various other regular and irregular shapes. For example, a flexible substrate according to the present disclosure may comprise a spiral or coil shape, while retaining flexibility and geometric efficiency.

Light emitting devices of embodiments according to the present disclosure overcome further light distribution deficiencies of conventional light emitting devices. Conventional lighting devices employing LED filaments are typically configured with LEDs on a single side of the filament. LEDs are “directional” light sources (e.g., LEDs are inherently configured to emit light in a specific and singular direction). Conventional lighting devices therefore produce poor omnidirectional light emission as a result of this single-sided configuration. Employing a twistable/rotatable substrate having LEDs disposed thereon overcomes this directionality deficiency, because the flexible substrate itself is conducive for dictating the direction of light emission. Light emitting devices according to the present disclosure may therefore achieve better, more omnidirectional light emission over conventional lighting devices.

Moreover, conventional lighting devices necessarily employ transparent or translucent filament substrates to compensate for their single-sided configuration. By employing twistable substrates, light emitting devices according to the present disclosure may be configured having opaque or otherwise less than transparent/translucent substrates. Light emitting devices according to embodiments of the present disclosure may therefore provide users with a greater degree of aesthetic choice.

Given the above, it may therefore be desirable to configure a light emitting device according to embodiments of the present disclosure such that two or more flexible substrates are employed. Light emitting devices according to the present disclosure may employ multiple flexible substrates and still achieve improved omnidirectional light emission over conventional lighting devices.

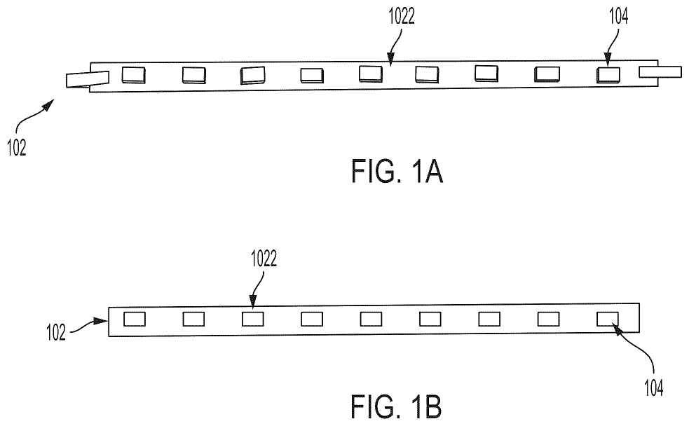

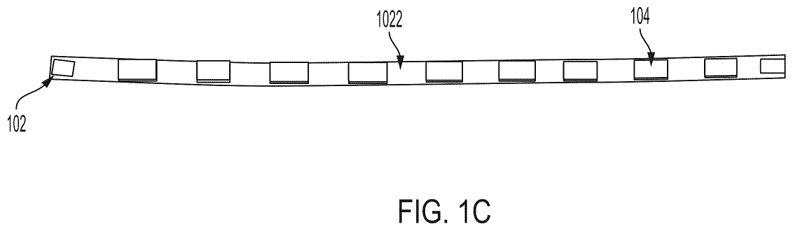

FIGS. 1A, 1B, and 1C are top views of an exemplary flexible substrate 102 configured in accordance with embodiments of the present disclosure. In embodiments, a flexible substrate 102 may comprise a substrate length, a substrate width, a first substrate surface 1022, and a second substrate surface (not shown). In embodiments, the flexible substrate 102 may be configured to be twistably and/or rotatably wrenched about a longitudinal axis that is parallel to the substrate length. The flexible substrate 102 of certain embodiments comprises material conducive for the twisting/rotating of the flexible substrate 102, including but not limited to plastic, polyamide. In embodiments, a plurality of LED packages 104 may be disposed on the first surface 1022 of the flexible substrate 102. The LED packages 104 of certain embodiments may have an LED package width and be configured to emit light outward from the flexible substrate 102. The plurality of LED packages 104 may be electrically connected in series with one another. FIG. 1A illustrates a first LED package width configuration, wherein the LED package width is less than the substrate width. As shown in FIG. 1B, the LED package width of certain embodiments may be equal to or very nearly equal to the substrate width, so that the flexible substrate 102 blocks as little light as possible.

In embodiments, the flexible substrate 102 may be configured to radiate heat. That is, the flexible substrate 102 of certain embodiments may comprise material(s) suitably tolerant of the heat generated by the plurality of LED packages 104. In embodiments, the plurality of LED packages 104 may comprise phosphor-based LED packages. The phosphor-based LED packages 104 of certain embodiments may be configured to emit blue light. Moreover, in embodiments the flexible substrate 102 may be of a matching color as a phosphor color of the phosphor-based LED packages 104 so as to camouflage the flexible substrate 102. The flexible substrate 102 may be configured as opaque or may be less than transparent. The flexible substrate 102 may be configured with metal contact ends for soldering to support wires. The metal contact ends of the flexible substrate 102 may comprise electrical contact pads for mechanical and electrical connection. In embodiments, the flexible substrate 102 may comprise polyamide. In embodiments, the substrate width and each LED package width may be the same width such that the flexible substrate 102 blocks as little light as possible. In embodiments, the substrate width of the flexible substrate 102 may be 1 to 2 millimeters, and the substrate length of the flexible substrate 102 may be 5 centimeters.

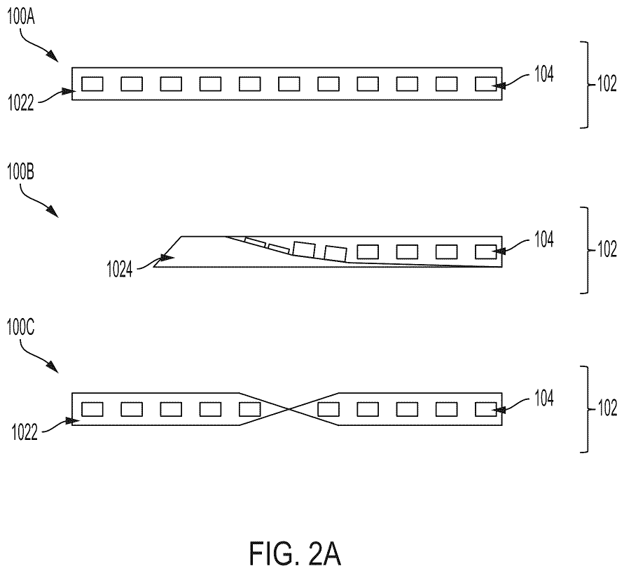

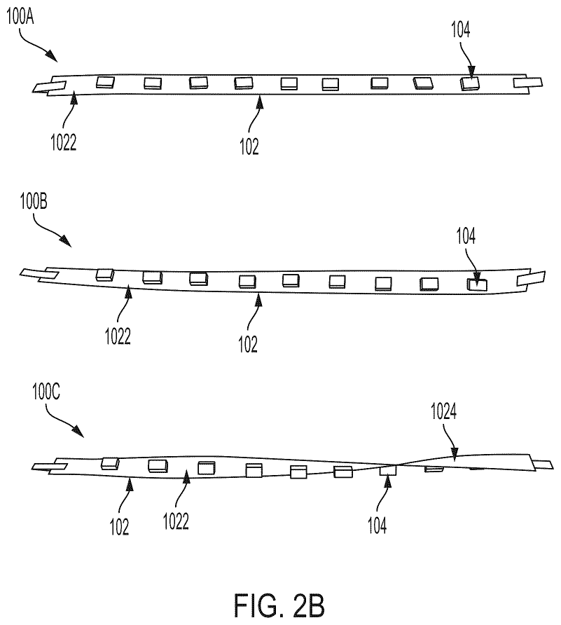

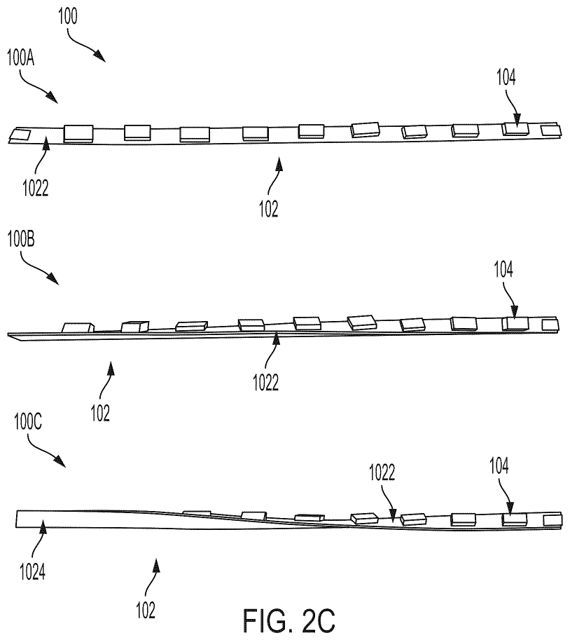

FIG. 2A is a top view illustration of the range of rotation of an exemplary flexible substrate 102 configured in accordance with embodiments of the present disclosure. FIGS. 2B-2C are perspective views of the range of rotation of an exemplary flexible substrate 102 configured in accordance with embodiments of the present disclosure. In embodiments, the flexible substrate 102 may be configured to be permanently flexible. That is, the flexible substrate 102 may retain the shape into which the flexible substrate 102 is twisted and/or rotated upon release of the torque causing the flexible substrate 102 to be twisted and/or rotated about a longitudinal axis parallel to the substrate length of the flexible substrate 102. The flexible substrate 102 may be configured to be twisted and/or rotated at least 360°. An exemplary flexible substrate 102 may be configured to be twisted and/or rotated within a range of 90° to 180°. In embodiments, exemplary flexible substrate 102 may be configured to be twisted and/or rotated within a range of 180° to 360°. In embodiments, exemplary flexible substrate 102 may be configured to be twisted and/or rotated within a range of 0° to 90°.

A relaxed or untwisted flexible substrate 102 is shown by 100A. The LED packages 104 are disposed facing in a uniform direction when the flexible substrate 102 is relaxed. A flexible substrate 102 twisted approximately 90° is shown by 100B. As shown, a first subset of LED packages 104 are disposed facing in a direction nearly perpendicular to a second subset of LED packages 104. A flexible substrate 102 twisted approximately 180° is shown by 100C. An example visual hallmark of a 180° rotation is that the second substrate surface 1024 now becomes visible. Further, a first subset of LED packages 104 are now disposed facing antiparallel (e.g., in the opposite direction) to a second subset of LED packages 104.

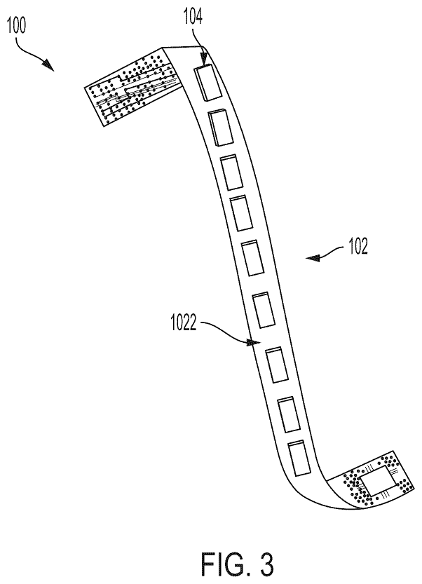

FIG. 3 is a perspective view of an exemplary flexible substrate 102 configured in accordance with embodiments of the present disclosure. In embodiments, the exemplary flexible substrate 102 may further comprise a circuit board having a first side 1022 and a second side 1024. A plurality of LED packages 104 may be disposed on and/or electrically and mechanically couplable to the first side 1022. A plurality of leads/traces 302 may be disposed on and/or electrically and mechanically couplable to the first side 1022 or second side 1024 and with the plurality of LED packages 104. For example, the LED packages 104 may couplable to the first side 1022 by e.g., wire bonding or soldering. Driver circuitry 304 may be any driver circuitry suitable for converting blue-phosphor LEDs to white light with minimal energy lost as heat.

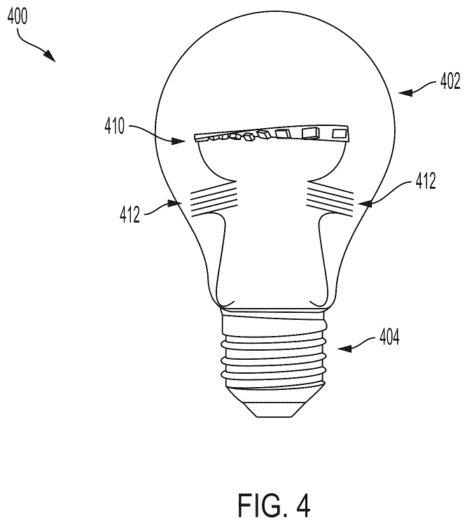

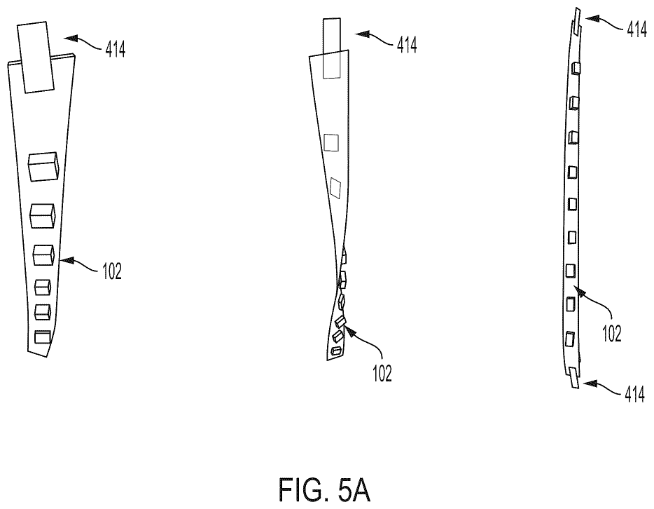

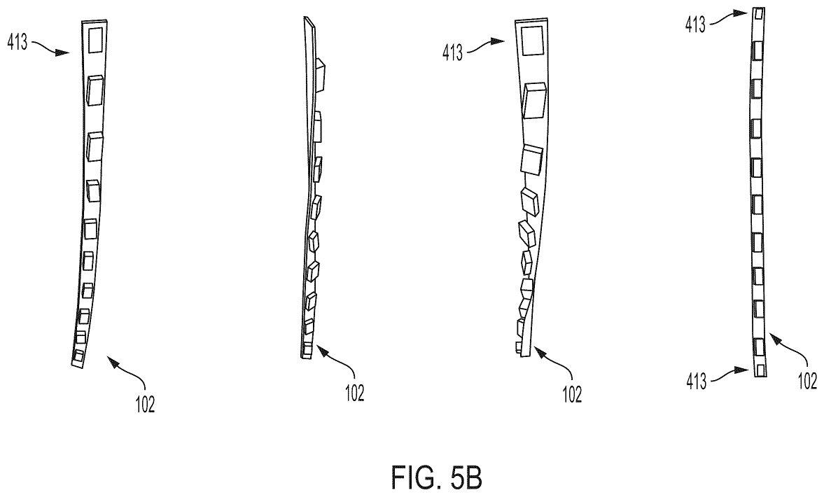

FIG. 4 illustrates an exemplary lighting apparatus 400 configured in accordance with embodiments of the present disclosure. In embodiments, the lighting apparatus 400 comprises a transparent housing 402. The transparent housing 402 of certain embodiments may be configured to house a lighting emitting device 410. In embodiments, the lighting apparatus 400 comprises a base 404 for electrically coupling with a lighting socket. The lighting emitting device 410 of certain embodiments is electrically couplable with the base 404 and is housed within the transparent housing 402. The light emitting device 410 may be mounted within the transparent housing 402 with supporting wires 412. In embodiments, the lighting emitting device 410 comprises a flexible substrate 102. The flexible substrate 102 may be configured with metal contact ends. The metal contact ends 413 of the flexible substrate 102 may comprise electrical contact pads 414 for mechanical and electrical connection of the light emitting device 410 with the base 404 (see, e.g., FIGS. 5A-5B). For example, the supporting wires 412 may be electrically and mechanically couplable to the electrical contact pads 414 of the flexible substrate 102. The supporting wires 412 may thus couple the flexible substrate 102 of the light emitting device 410 with the base 404, via the electrical contact pads 414. Alternatively, the flexible substrate 102 may be coupled to a supporting structure independent of metal contact ends. The base 404 of certain embodiments may be configured as a variety of light bulb base types (e.g., Edison (e.g., E10, E11, E26), G4, G6.35, GY6.35, and the like). In embodiments, the base 404 is mechanically and/or electrically couplable to the circuit board 102 of the light emitting device 410 of certain embodiments, such that electrical current is provided to the light emitting device 410.

The flexibility of the flexible substrate 102 may be either temporary or permanent. When the flexibility is temporary, the flexible substrate 102 is electrically and mechanically coupled to the supporting wires 412 prior to having a suitable torque applied so as to configure it in a twisted orientation. Alternatively, a permanently flexible substrate 102 may be configured in a twisted orientation prior to being electrically and mechanically coupled to the supporting wires 412. For example, a mixture of phosphor and silicone/epoxy may first be applied to the flexible substrate 102. The flexible substrate 102 may then be configured to the desired rotation and, while maintaining the desired configuration, secured to the supporting wires 412. The flexible substrate 102 may therefore permanently maintain its configuration. Alternatively, the flexible substrate 102 may comprise material naturally conducive to maintaining permanent flexibility (e.g., copper).

FIGS. 5A-5B are perspective views illustrating a flexible substrate 102 according to various embodiments. FIG. 5A illustrates a flexible substrate 102 configured with electrical contact pads 414. FIG. 5B illustrates a flexible substrate 102 configured with metal contact ends 413 that may or may not comprise electrical contact pads 414. In embodiments, the metal contact ends 413 may be suitable for soldering to the supporting wires 412.

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1-20. (canceled)

21. A light emitting device, comprising:
a flexible substrate having a first substrate surface; and
a plurality of LED packages disposed on the first substrate surface, wherein the plurality of LED packages comprises phosphor-based LED packages and the flexible substrate is of a matching color as a phosphor color of the phosphor-based LED packages.

22. The light emitting device of claim 21, wherein one or more LED packages of the plurality of LED packages is configured to emit light outward from the flexible substrate.

23. The light emitting device of claim 21, wherein the flexible substrate has a substrate length.

24. The light emitting device of claim 23, wherein the flexible substrate is configured to be flexibly wrenched about a longitudinal axis that is parallel to the substrate length.

25. The light emitting device of claim 24, wherein the flexible substrate is configured to be twistably or rotatably wrenched about the longitudinal axis.

26. The light emitting device of claim 21, wherein the flexible substrate is configured to be twisted and/or rotated within a range of one or more of 0° to 90°, 90° to 180°, or 180° to 360°.

27. The light emitting device of claim 21, wherein the flexible substrate is configured to radiate heat.

28. The light emitting device of claim 21, wherein the flexible substrate further comprises:
a circuit board comprising a first side and a second side;
the plurality of LED packages disposed on and/or electrically and mechanically couplable to the first side;
a plurality of leads/traces disposed on and/or electrically and mechanically couplable to one or more of the first side or second side and electrically couplable with the plurality of LED packages; and
driver circuitry disposed on and/or electrically and mechanically couplable with one or more of the first side or second side.

29. The light emitting device of claim 28, wherein, the driver circuitry is electrically couplable with the plurality of leads/traces of the circuit board.

30. The light emitting device of claim 21, wherein one or more of the plurality of LED packages are configured to emit blue light.

31. The light emitting device of claim 21, wherein one or more LED packages of the plurality of LED packages comprises an LED package width.

32. The light emitting device of claim 31, wherein a substrate width of the flexible substrate is one or more of equivalent to or greater than at least one LED package width.

33. The light emitting device of claim 21, wherein the flexible substrate comprises polyamide.

34. The light emitting device of claim 33, wherein the flexible substrate has a substrate width of 1 to 2 mm and a substrate length of 5 cm.

35. A lighting apparatus, comprising:
a transparent housing;
a base for electrically coupling with a lighting socket; and
a light emitting device electrically couplable with the base and housed within the transparent housing, wherein the light emitting device comprises:
a flexible substrate having a substrate length and a first substrate surface; and
a plurality of LED packages disposed on the first substrate surface, wherein the plurality of LED packages comprises phosphor-based LED packages and the flexible substrate is of a matching color as a phosphor color of the phosphor-based LED packages.

36. The lighting apparatus of claim 35, wherein the flexible substrate configured to be flexibly wrenched about a longitudinal axis that is parallel to a substrate length of the flexible substrate.

37. The lighting apparatus of claim 35, wherein each LED package of the plurality of LED packages is configured to emit light outward from the flexible substrate.

38. The lighting apparatus of claim 35, wherein the base comprises one or more of an Edison-type base, a G4-type base, a G6.35-type base, a G6.35-type base, a G9-type base.

39. The lighting apparatus of claim 35, wherein the flexible substrate further comprises:
a circuit board, the circuit board having a first side and a second side;
a plurality of LED packages disposed on and/or electrically and mechanically couplable to the first side;
a plurality of leads/traces disposed on and/or electrically and mechanically couplable to one or more of the first side or second side and electrically couplable with the plurality of LED packages; and
driver circuitry disposed on and/or electrically and mechanically couplable with one or more of the first side or second side, the driver circuitry electrically couplable with the plurality of leads/traces of the circuit board.

40. The lighting apparatus of claim 39, wherein the base is mechanically and/or electrically couplable to the circuit board of the light emitting device such that electrical current is provided to the light emitting device.
